(19) United States
(12) Patent Application Publication
(10) Pub. No.: US 2021/0141018 A1
(43) Pub. Date: May 13, 2021

(54) METHOD FOR DETERMINING AN ESTIMATED CURRENT OF A THREE-PHASE ELECTRIC MOTOR IN DEGRADED MODE

(71) Applicants: Continental Automotive France, Toulouse (FR); Continental Automotive GmbH, Hannover (DE)

(72) Inventors: Michel Parette, Toulouse (FR); Rodolphe Jaumouillé, Toulouse (FR)

(21) Appl. No.: 17/053,490

(22) PCT Filed: Apr. 16, 2019
(86) PCT No.: PCT/FR2019/050891

§ 371 Date: Nov. 6, 2020

(30) Foreign Application Priority Data
May 7, 2018 (FR) 1853929

(51) Int. Cl. G01R 31/34; G01R 27/02; G01R 19/00

(52) U.S. Cl. CPC G01R 31/343; B62D 5/049; G01R 19/0046; G01R 27/02

(57) ABSTRACT

A method for determining an estimated current flowing through a winding of a motor that is then controlled on two active phases. A measured voltage is measured for each of the two active phases at the input of the winding, the two measured voltages are corrected to produce a respective corrected voltage, a temperature-compensated resistance of the motor is determined, and at least one estimated current flowing through each of the two active phases, respectively, of the winding is determined on the basis of the temperature-compensated resistance of the motor and the measured voltages of the two active phases.

### CROSS REFERENCE TO RELATED APPLICATIONS

This application is the U.S. National Phase application of PCT International Application No. PCT/FR2019/050891, filed Apr. 16, 2019, which claims priority to French Patent Application No. 1853929, filed May 7, 2018, the contents of such applications being incorporated by reference herein.

### FIELD OF THE INVENTION

The present invention relates to a method for determining an estimated current flowing through a winding of a permanent-magnet synchronous three-phase electric motor of the type comprising at least one winding controllable by a switching device, the motor then being controlled on two active phases in a degraded mode. A degraded mode means that the motor is controlled on two phases, the third phase being considered to be faulty and being placed in the open state.

The method for determining a current can then be used in a method for diagnosing a validity of measurements of a measured current flowing through a respective phase of a winding of a synchronous three-phase electric motor, in particular in order to detect a fault in a current sensor.

The present invention is preferably applied to the automotive field, in particular to a power-steering motor for a motor vehicle, but is not limited thereto.

### BACKGROUND

According to the prior art, a method is known for estimating an estimated current flowing through a winding of an electric motor of the type comprising at least one winding controllable by a switching device. The switching device is connected to the input of the winding and receives a control in the form of a control voltage at its input and transforms it into a voltage that is applied to the input of the winding.

The control voltage is most commonly an AC voltage. A unit transforms the control voltage into a pulse-width modulated voltage, a duty cycle of which is equal to the value of the control voltage.

This pulse-width modulated voltage is used to switch a first switch connected between the winding and a substantially constant potential, while the opposite voltage of the modulated voltage is used to switch a second switch connected between the winding and a ground. In this way, the two controls are substantially in phase opposition and the open states of the two switches are such that at most one of the two switches is switched/on at a given instant, the other being unswitched/off at the same instant.

A transformation module is capable of receiving the control voltage and of separately controlling the opening of the two switches on the basis of the control voltage.

The estimation method described in this instance of prior art comprises the step of measuring a measured voltage at the input of the winding, the step of correcting the measured voltage to produce a corrected voltage, the step of determining a resistance of the switching device and the step of determining at least one estimated current flowing through the winding by dividing the difference between a control voltage used to control the switching device and the corrected voltage by the resistance.

Although this solution makes it possible to obtain an individualized estimate of the current flowing through each winding and to detect the fault in the current-measuring stage by estimating the currents by using the difference between the control applied to the motor and the measurement of this control, it has the drawback that it cannot be used at high speeds of the motor. Moreover, and above all, this solution is not robust in terms of its fault detection in degraded mode.

Another instance of prior art, which is described in particular by the document FR-A-3 039 283, incorporated herein by reference, relates to a method that makes it possible to detect a fault in the current-measuring stage for the motor phases, or in the permanent-magnet three-phase synchronous motor controlled by an inverter or the inverter itself.

The types of fault detected are a short circuit or a loss of the current measurement for one or more motor phases, a measured current for one or more phases that are implausible on account of an offset and/or gain error in the current measurement for the motor phase, for example, of a short circuit to ground or between phases or a loss of one or more phases, of parameters of the controlled motor that are implausible, indicating a significant imbalance of the impedances of the motor, an inverter that is unbalanced due to an excessive resistance of a power switch.

The drawback of the solution proposed by this document is that the diagnosis of the current measurement cannot be carried out when the system is in degraded mode.

A third solution has been proposed by another instance of prior art to allow a fault in the current-measuring stage to be detected. It has been proposed to use a current sensor for each phase of the motor and to check the consistency between these current sensors by means of the nodal rule, which stipulates that the sum of the three currents of the three phases must be zero.

The drawback of this third solution is the cost thereof and the physical implementation thereof on a circuit board, since provision is made for adding a current sensor and the associated elements thereof and also connecting said current sensor by means of a new analog input at the microcontroller, and on account of the increase in the surface area of the circuit board so as to accommodate these new components.

### SUMMARY OF THE INVENTION

The problem on which an aspect of the present invention is based is that of determining, for a synchronous three-phase electric motor controlled by a switching device, an estimated current flowing through a winding of the electric motor while the motor is operating in degraded mode, one electrical power supply phase of the motor being in an open state.

To this end, an aspect of the present invention relates to a method for determining an estimated current flowing through a winding of a permanent-magnet synchronous three-phase electric motor of the type comprising at least one winding controllable by a switching device, which is noteworthy in that it comprises the following steps, the motor then being controlled on two active phases, a third phase being in an open state:
measuring a measured voltage for each of the two active phases at the input of the winding,
correcting the two measured voltages to produce a respective corrected voltage,
determining a temperature-compensated resistance of the motor,
determining at least one estimated current flowing through one of the two active phases, respectively, of the winding on the basis of the temperature-compensated resistance Rmot of the motor and the measured voltages Umesx, Umesy of the two active phases by solving the following equations, x being the first active phase and y being the second active phase of the two active phases:

$$[ Iestx ] = \frac{\begin{matrix}\begin{matrix}[ Umesx - ( \frac{Umesx + Umesy}{2} ) ] - \\ [ Lmot ] [ \frac{dImesx}{dt} ] + \frac{\sqrt{3}}{2} * Φ *\end{matrix} \\ {ω}_{mot} * sin ( θ mot + \frac{π}{6} - k \frac{2 π}{3} )\end{matrix}}{[ Rmot ]} \\ [ Iesty ] = \frac{\begin{matrix}\begin{matrix}[ Umesy - ( \frac{Umesx + Umesy}{2} ) ] - \\ [ Lmot ] [ \frac{dImesy}{dt} ] + \frac{\sqrt{3}}{2} * Φ *\end{matrix} \\ {ω}_{mot} * sin ( θ mot + \frac{π}{6} - k \frac{2 π}{3} )\end{matrix}}{[ Rmot ]}$$

in which equations Lmot is an inductance of the motor at 20° C. and 0 ampere, Φ is a flux of the motor at 20° C. and 0 ampere, ωₘₒₜ is a speed of rotation of the motor, θₘₒₜ is an angular position of a rotor of the motor, k being a constant equal to 0 for phase 1, to 1 for phase 2 and to 2 for phase 3.

An aspect of the present invention makes it possible to overcome all the drawbacks of the two instances of prior art described above. This is achieved without any new component to be added or any increase in cost apart from a small software design cost. Moreover, and above all, an aspect of the present invention makes it possible to determine an estimated current when the motor is operating in degraded mode, one of the three phases being open.

The method for detecting the faults, which may be the faults mentioned above, consists in identifying an error in the dynamic behavior of the currents estimated on the basis of an electrical model of the permanent-magnet synchronous motor relative to the measured currents of the motor phases.

Advantageously, the estimated currents are determined by using a numerical analysis method for approximation of differential equations.

Advantageously, the selected numerical analysis method for approximation of differential equations is the second-order Runge-Kutta method, with the following equations for calculating the estimated current Iestx for phase x, which is one of the two active phases:

$${[ \frac{dIestx}{dt} ]}_{n} = \frac{\begin{matrix}\begin{matrix}[ Umesx - ( \frac{Umesx + Umesy}{2} ) ] - \\ [ Rmot ] [ {Iestx}_{n} ] + \frac{\sqrt{3}}{2} * Φ *\end{matrix} \\ {ω}_{mot} * sin ( θ mot + \frac{π}{6} - k \frac{2 π}{3} )\end{matrix}}{[ Lmot ]} \\ [ {Iestx}_{n + \frac{1}{2}} ] = [ {Iestx}_{n} ] + {{\frac{Δ t}{2} [ \frac{dIestx}{dt} ]}_{n} \\ [ \frac{dIestx}{dt} ]}_{n + \frac{1}{2}} = \frac{\begin{matrix}\begin{matrix}[ Umesx - ( \frac{Umesx + Umesy}{2} ) ] - \\ [ Rmot ] [ {Iestx}_{n + \frac{1}{2}} ] + \frac{\sqrt{3}}{2} * Φ *\end{matrix} \\ {ω}_{mot} * sin ( θ mot + \frac{π}{6} - k \frac{2 π}{3} )\end{matrix}}{[ Lmot ]} \\ [ {Iestx}_{n + 1} ] = [ {Iestx}_{n} ] + Δ {t [ \frac{dIestx}{dt} ]}_{n + \frac{1}{2}}$$

in which Δt is the sampling time for the calculation and n is the number of iterations, the equations for calculating the estimated current for phase y, which is the other one of the two active phases, being similar, with x being swapped for y and vice versa in the above equations.

Advantageously, the correction of the two measured voltages to produce a respective corrected voltage is carried out initially by filtering of the measured voltages, which are then in the form of square waves, by means of a low-pass filter to produce a respective sinusoidal voltage, and then by compensation of the respective sinusoidal voltages by means of a compensator capable of compensating for the attenuating effects of the low-pass filter to produce a respective corrected voltage.

Advantageously, the low-pass filter is a second- or higher-order low-pass filter.

Advantageously, the compensation uses an interpolation table on the basis of a speed of rotation of the motor.

Advantageously, the determination of the resistance of the motor is temperature-compensated by taking a mean temperature Tmos of the electronic elements of the switching device that are located near a temperature sensor, the resistance Rmot being compensated according to the following equation:

Rmot=Rmot20*(1+0.004*(Tmos−20° C.))

0.004 being the temperature coefficient of copper, and Rmot20 corresponding to the resistance of one phase of the motor at 20° C.

An aspect of the invention also relates to a method for diagnosing a validity of measurements of a measured current flowing through a respective phase of a winding of a permanent-magnet synchronous three-phase electric motor of the type comprising at least one winding controllable by a switching device, the motor then being controlled on two active phases, a third phase being in an open state, which is noteworthy in that:
the measured current flowing through at least one of the two active phases is measured,
an estimated current flowing through at least one of the two active phases of the winding is determined by means of such an estimation method,
a respective sliding standard deviation, for at least one of the two active phases, of a difference between the measured current and the estimated current for said at least one of the two active phases over a sliding horizon of a number of samples is calculated according to one of the following formulae, respectively:

$$Iecx = \sqrt{\frac{{\sum }_{i = 1}^{i = NbSample} {( Imesx - Iestx )}^{2}}{NbSample}}$$

$$or$$

$$Iecy = \sqrt{\frac{{\sum }_{i = 1}^{i = NbSample} {( Imesy - Iesty )}^{2}}{NbSample}}$$

NbSample being the number of samples,
the respective sliding standard deviation for said at least one of the two active phases is compared with a predetermined threshold value, wherein, when the standard deviation is higher than the predetermined threshold value, an error in the measured currents is diagnosed for said at least one phase and, when the standard deviation is lower than the predetermined threshold value, a validity of the measured currents is diagnosed for said at least one of the two active phases.

An aspect of the present invention relates to a method performed in parallel with a current control for detecting a fault in the current-measuring stage for the motor phases, or in the permanent-magnet three-phase synchronous motor controlled by an inverter or the inverter itself, which makes it possible to establish a diagnosis of a validity of measurements of a measured current.

This diagnosis detection method is applicable only in degraded mode, i.e. when the permanent-magnet three-phase synchronous motor is controlled on two, rather than three, phases.

The types of fault diagnosed can relate to a short circuit and/or a loss of the current measurement for one or more motor phases, a measured current for one or more phases that is implausible with offset and/or gain errors in the current measurement for a motor phase, for example, a short circuit to ground or between phases and/or a loss of one or more phases of the motor.

An aspect of the present invention offers the possibility of substituting an estimated current for the erroneously measured current and of continuing to control the motor in degraded mode on the basis of this estimated current.

Advantageously, the diagnosis method is implemented on the two active phases, with or without measurement of the current in the second active phase and, when the current is not measured in the second active phase, the value of the current in this second active phase is extrapolated from the measured current of the first active phase, being equal to the negative value of the current of the first phase, the standard deviation being calculated according to the above formula given for this second phase.

Advantageously, the samples are taken in a range of angular positions of the motor corresponding to a stabilized current in said at least one of the two phases.

Advantageously, it is applied to a physical or virtual current sensor capable of measuring a current in said at least one of the two active phases, the current sensor being characterized as faulty when the standard deviation is higher than the predetermined threshold value.

### BRIEF DESCRIPTION OF THE DRAWINGS

Other features, aims and advantages of aspects of the present invention will become apparent on reading the detailed description that follows and on examining the appended drawings provided by way of non-limiting examples, in which:

FIG. 1 illustrates a method according to an aspect of the present invention for diagnosing a validity of measurements of a measured current flowing through a respective phase of a winding of a permanent-magnet synchronous three-phase electric motor of the type comprising at least one winding controllable by a switching device, the motor then being controlled on two active phases, which is performed by calculating a deviation between the measured current and the estimated current for the two active phases,

FIG. 2 shows a flow diagram of the diagnosis method according to one embodiment of the present invention,

FIGS. 3A and 3B show current intensity and torque curves for angles of rotation of the motor, these curves being employed to define a sampling zone.

### DETAILED DESCRIPTION OF THE PREFERRED EMBODIMENTS

Referring more particularly to FIG. 1, an aspect of the present invention relates to a method for determining an estimated current Iestx, Iesty flowing through a winding of a permanent-magnet synchronous three-phase electric motor M of the type comprising at least one winding controllable by a switching device 11.

In FIG. 1, it is an inverter that bears the reference 11 given to the switching device, the inverter being part of the switching device.

This determination method takes place with a motor M that is then controlled on two active phases, a third phase being in an open state.

The switching device comprises a DC-to-AC inverter 11 that is supplied with power by an external source at a DC voltage Ubat, which may be the voltage of a battery of a motor vehicle. The inverter 11 transforms a DC voltage into a square-wave voltage, for which the voltages of the two phases x and y supplying power to the motor M are Ux and Uy, respectively.

A voltage is measured for each of the two active phases at the input of the winding. The two measured voltages Ux, Uy are then corrected to produce a respective corrected voltage. This correction is carried out in two consecutive modules 1 and 2.

In the first module 1, which may advantageously be a low-pass filter, the measured voltages are square-wave voltages at the input, and at the output the obtained voltages are sinusoidal voltages.

In the second module 2, which is a compensation module 2 or a compensator, the respective sinusoidal voltages are respectively compensated by a compensator capable of compensating for the attenuating effects of the low-pass filter to produce a respective corrected measured voltage Umesx and Umesy.

In parallel with the corrected measured voltages Umesx and Umesy being obtained, a temperature-compensated phase electrical resistance of the motor M is determined. This is carried out consecutively in the modules 3 and 4 on the basis of a temperature Tsens detected by a sensor near the switching device and the electronic elements to give a temperature of the switching device Tmos. This temperature is extrapolated to give the temperature of the motor M and to proceed to correct the resistance of the motor M.

On the basis of the corrected measured voltages Umesx and Umesy and of the temperature-compensated electrical resistance Rmot of the motor M, at least one estimated current Iestx or Iesty flowing through one of the two active phases, respectively, of the winding is determined by solving the following equations, x being the first active phase and y being the second active phase of the two active phases:

$$[ Iestx ] = \frac{\begin{matrix}\begin{matrix}[ Umesx - ( \frac{Umesx + Umesy}{2} ) ] - \\ [ Lmot ] [ \frac{dImesx}{dt} ] + \frac{\sqrt{3}}{2} * Φ *\end{matrix} \\ {ω}_{mot} * sin ( θ mot + \frac{π}{6} - k \frac{2 π}{3} )\end{matrix}}{[ Rmot ]} \\ [ Iesty ] = \frac{\begin{matrix}\begin{matrix}[ Umesy - ( \frac{Umesx + Umesy}{2} ) ] - \\ [ Lmot ] [ \frac{dImesy}{dt} ] + \frac{\sqrt{3}}{2} * Φ *\end{matrix} \\ {ω}_{mot} * sin ( θ mot + \frac{π}{6} - k \frac{2 π}{3} )\end{matrix}}{[ Rmot ]}$$

in which equations Lmot is an inductance of the motor M at 20° C. and 0 ampere, Φ is a flux of the motor M at 20° C. and 0 ampere, ωₘₒₜ is a speed of rotation of the motor M, θₘₒₜ is an angular position of a rotor of the motor M, k being a constant equal to 0 for phase 1, to 1 for phase 2 and to 2 for phase 3.

This is carried out in an estimation module for estimating the currents flowing through each phase, which is referenced 5 in FIG. 1, with the two estimated currents Iestx and Iesty at the output of the estimation module 5.

The determination is carried out on the basis of an electrical model in degraded mode of a permanent-magnet three-phase synchronous motor M, with the assumption that the system is balanced, i.e. that there is no impedance imbalance between the active phases of the motor M.

There are a plurality of ways to solve the above equations, and two preferred ways are described below. The estimated currents Iestx, Iesty can be determined by using a numerical analysis method for approximation of differential equations.

In a first optional embodiment, which is not preferred, a Euler method can be applied in a single iteration according to the following equations:

$${[ \frac{dIestx}{dt} ]}_{n} = \frac{\begin{matrix}\begin{matrix}[ Umesx - ( \frac{Umesx + Umesy}{2} ) ] - \\ [ Rmot ] [ {Iestx}_{n} ] + \frac{\sqrt{3}}{2} * Φ *\end{matrix} \\ {ω}_{mot} * sin ( θ mot + \frac{π}{6} - k \frac{2 π}{3} )\end{matrix}}{[ Lmot ]} \\ [ {Iestx}_{n + 1} ] = [ {Iestx}_{n} ] + Δ {t [ \frac{dIestx}{dt} ]}_{n}$$

In a second, preferred optional embodiment, the selected numerical analysis method for approximation of differential equations may be the second-order Runge-Kutta method.

The following equations can then be solved to calculate the estimated current Iestx for phase x, which is one of the two active phases:

$${[ \frac{dIestx}{dt} ]}_{n} = \frac{\begin{matrix}\begin{matrix}[ Umesx - ( \frac{Umesx + Umesy}{2} ) ] - \\ [ Rmot ] [ {Iestx}_{n} ] + \frac{\sqrt{3}}{2} * Φ *\end{matrix} \\ {ω}_{mot} * sin ( θ mot + \frac{π}{6} - k \frac{2 π}{3} )\end{matrix}}{[ Lmot ]} \\ [ {Iestx}_{n + \frac{1}{2}} ] = [ {Iestx}_{n} ] + {{\frac{Δ t}{2} [ \frac{dIestx}{dt} ]}_{n} \\ [ \frac{dIestx}{dt} ]}_{n + \frac{1}{2}} = \frac{\begin{matrix}\begin{matrix}[ Umesx - ( \frac{Umesx + Umesy}{2} ) ] - \\ [ Rmot ] [ {Iestx}_{n + \frac{1}{2}} ] + \frac{\sqrt{3}}{2} * Φ *\end{matrix} \\ {ω}_{mot} * sin ( θ mot + \frac{π}{6} - k \frac{2 π}{3} )\end{matrix}}{[ Lmot ]} \\ [ {Iestx}_{n + 1} ] = [ {Iestx}_{n} ] + Δ {t [ \frac{dIestx}{dt} ]}_{n + \frac{1}{2}}$$

in which Δt is the sampling time for the calculation and n is the number of iterations, the other parameters having been identified previously.

For phase y, the equations for calculating the estimated current Iesty for phase y, which is the other one of the two active phases, are similar, with x being swapped for y and y for x in the above equations.

Returning to the correction of the two measured voltages in the modules 1 and 2, this correction of the two measured voltages to produce a respective corrected voltage can be carried out initially by filtering 1 of the measured voltages, which are then in the form of square waves, by means of a low-pass filter in the module 1 to produce a respective sinusoidal voltage, and then by compensation 2 of the respective sinusoidal voltages by means of a compensator capable of compensating for the attenuating effects of the low-pass filter to produce a respective corrected voltage.

During the filtering 1, the low-pass filter may be a second- or higher-order low-pass filter for filtering the square-wave voltages applied to the motor phases M, which allows demodulation by filtering the carrier corresponding to the frequency of the pulse-width modulations of a system for pulse-width modulation of the voltage.

During the compensation 2, an interpolation table on the basis of a speed of rotation ωₘₒₜ of the motor M can be used by way of a position speed module 10. The reduction in the gain of the amplitudes of at least one of the two voltages of the active phases due to the filters is thus corrected on the basis of the speed of rotation ωₘₒₜ of the motor M. The position speed module 10 is the measurement of speed and position module for the rotor of the motor M.

With regard to the determination of the resistance of the motor M, the resistance of the motor M can be temperature-compensated by taking the resistance Rmot20 of the motor M at ambient temperature, which is known.

To this end, a mean temperature Tmos of the electronic elements of the switching device that are arranged near a temperature sensor that detects a temperature Tsens can be taken. The resistance Rmot of the motor M can then be compensated on the basis of the mean temperature Tmos of the electronic elements of the switching device 11 according to the following equation:

Rmot=Rmot20*(1+0.004*Tmos−20° C.)

0.004 being the temperature coefficient of copper, and Rmot20 corresponding to the resistance of one phase of the motor M at 20° C.

A preferred application of the method for determining an estimated current Iestx, Iesty flowing through a winding of a motor M is intended for a method for diagnosing a validity of measurements of a measured current flowing through a respective phase of a winding of a permanent-magnet synchronous three-phase electric motor M of the type comprising at least one winding controllable by a switching device 11, the motor M then always being controlled on two active phases, a third phase being in an open state.

In this method, the measured current flowing through at least one of the two active phases, advantageously through both active phases, is measured. This is carried out by the measurement module 9 in FIG. 1, this measurement module 9 being able to measure a current of one phase or the currents Imesx, Imesy of two active phases.

An estimated current Iestx, Iesty flowing through at least one of the two active phases of the winding is also determined by means of the estimation method as described above, with the estimated current values Iestx, Iesty being obtained.

Then, a respective sliding standard deviation, for at least one of the two active phases, of a difference between the measured current and the estimated current Iestx, Iesty for said at least one of the two active phases over a sliding horizon of a number of samples is calculated according to one of the following formulae, respectively, which are for one of the two phases, respectively:

$$Iecx = \sqrt{\frac{{\sum }_{i = 1}^{i = NbSample} {( Imesx - Iestx )}^{2}}{NbSample}}$$

$$or$$

$$Iecy = \sqrt{\frac{{\sum }_{i = 1}^{i = NbSample} {( Imesy - Iesty )}^{2}}{NbSample}}$$

NbSample being the number of samples.

Finally, the respective sliding standard deviation for said at least one of the two active phases is compared with a predetermined threshold value. When the standard deviation is higher than the predetermined threshold value, an error in the measured currents Imesx or Imesy is diagnosed for said at least one phase, while, when the standard deviation is lower than the predetermined threshold value, a validity of the measured currents Imesx or Imesy is diagnosed for said at least one of the two active phases.

The predetermined threshold value may take into account the worst-case measurement errors by taking into account the whole of the measurement chain and all the possible drifts, including thermal, sampling, power supply, calibration, and other drifts.

FIG. 1 shows a fault-detection module 6 that implements the diagnosis method described above by evaluating a standard deviation or the standard deviations lecx and lecy. One or more measured current values Imesx and Imesy, and one or more estimated current values Iestx, Iesty for at least one phase, and preferably for both active phases, are transmitted at the input of this fault-detection module 6.

The diagnosis method according to an aspect of the invention can be implemented on the two active phases. This can be carried out with or without measurement of the current in the second active phase. If the current is not measured for the second active phase, the value of the measured current in this second active phase is extrapolated from the measured current Imesx or Imesy of the first active phase, being equal to the negative value of the current of the first phase, the standard deviation being calculated according to the above formula given for this second phase.

FIG. 2 shows a flow diagram of the diagnosis method according to an aspect of the present invention, including the method for determining an estimated current Iestx, Iesty.

In a branch of the flow diagram on the left-hand side, one or more measured voltage measurements Ux, Uy are corrected in a filtering operation 1 and a compensation operation 2 to give one or more corrected voltage measurements Umesx, Umesy.

In parallel, a phase electrical resistance Rmot20 of the motor is taken at ambient external temperature during stoppage of the motor M, said resistance being compensated by calculating a temperature taken by a sensor and extrapolated to the electronic elements of the switching device near the motor M at reference 3, and then by compensating the resistance of the motor M by means of this extrapolated temperature at reference 4 to obtain a compensated electrical resistance Rmot of the motor.

The estimated intensity Iestx, Iesty, for one phase or for both phases, of the one or more currents flowing through one or each phase, is then calculated at reference 5.

One or more measured current values Imesx, Imesy, which are advantageously measured by a sensor, are supplied at 9 on the basis of the actual current intensity or intensities Ix, Iy at the input of the motor. These measured values may differ from the actual current intensity values Ix, Iy, if the measurement is faulty.

At reference 6, a fault in the measurements of the current intensities is detected by evaluating a respective sliding between standard deviation, for at least one of the two active phases, of a difference between the measured current Imesx, Imesy and the estimated current Iestx, Iesty for the active phase or both active phases.

For the diagnosis method, the number of samples NbSample is chosen to determine a horizon of a duration longer than a minimum value that is high enough to perform filtering and avoid false alerts.

Conversely, the number of samples NbSample is chosen to determine a horizon of a duration shorter than a maximum value that presents a risk in terms of continuing to control the motor M in the presence of a fault in the intensity measurement, for example in a sensor.

Without this being limiting, the horizon may be between 10 and 15 milliseconds, with a sampling period of 500 microseconds. In these cases, the number of samples may be between 20 and 30.

The samples should be taken in a range of angular positions of the motor M corresponding to a stabilized current in said at least one of the two phases.

FIGS. 3A and 3B show a current intensity I of the motor M and a motor torque C, respectively, as a function of the electrical angular position angle θmot of the motor for each of the two current phases.

The shape of the current in degraded mode is shown in FIG. 3A. Preferably, the detection of an error and the diagnosis method can be implemented in a zone in which the current remains relatively stabilized with a low variation gradient. This corresponds to the zone formed by the trough in FIG. 3A.

It is therefore advantageous for sampling of the currents to be diagnosed to take place only in the pit of this trough on the basis of the angular position of the electric motor M, in a range of electrical angular positions of the motor M the angle θmot is within a range corresponding to the trough.

Given a sampling window of 1 rad, and TetaRef1 being the reference, the reference window extends between TetaRef1−0.5 rad and TetaRef1+0.5 rad or between TetaRef1−0.5 rad+n and TetaRef1+0.5 rad+n; the method selects the measured current Imesx and the estimated current Iestx or Iesty with:

TetaRef1=0 rad if phase 1 is faulty

TetaRef1=2 n/3 if phase 2 is faulty

TetaRef1=4 n/3 rad if phase 3 is faulty.

This diagnosis is valid when the motor M is controlled on two phases.

Advantageously, it is applied to a physical current sensor, i.e. one that is actually present, or a virtual current sensor, in the latter case the software, which is capable of measuring a current in said at least one of the two active phases, the current sensor being characterized as faulty when the standard deviation is higher than the predetermined threshold value.

When a current sensor is characterized as faulty, the intensity measurement from said sensor can be replaced by an estimated current intensity measurement Iestx, Iesty. The motor M can then continue to be controlled with this new estimated current intensity value Iestx, Iesty.

1. A method for determining an estimated current (Iestx, Iesty) flowing through a winding of a permanent-magnet synchronous three-phase electric motor (M) of the type comprising at least one winding controllable by a switching device, the method comprising, the motor (M) then being controlled on two active phases, a third phase being in an open state:
measuring a measured voltage (Ux, Uy) for each of the two active phases at the input of the winding,
correcting the two measured voltages (Ux, Uy) to produce a respective corrected voltage (Umesx, Umesy),
determining a temperature-compensated resistance (Rmot) of the motor, and
determining at least one estimated current (Iestx, Iesty) flowing through each of the two active phases, respectively, of the winding on the basis of the temperature-compensated resistance (Rmot) of the motor and the measured voltages (Umesx, Umesy) of the two active phases by solving the following equations, x being the first active phase and y being the second active phase of the two active phases:
$$[ Iestx ] = \frac{\begin{matrix}\begin{matrix}[ Umesx - ( \frac{Umesx + Umesy}{2} ) ] - \\ [ Lmot ] [ \frac{dImesx}{dt} ] + \frac{\sqrt{3}}{2} * Φ *\end{matrix} \\ {ω}_{mot} * sin ( θ mot + \frac{π}{6} - k \frac{2 π}{3} )\end{matrix}}{[ Rmot ]} \\ [ Iesty ] = \frac{\begin{matrix}\begin{matrix}[ Umesy - ( \frac{Umesx + Umesy}{2} ) ] - \\ [ Lmot ] [ \frac{dImesy}{dt} ] + \frac{\sqrt{3}}{2} * Φ *\end{matrix} \\ {ω}_{mot} * sin ( θ mot + \frac{π}{6} - k \frac{2 π}{3} )\end{matrix}}{[ Rmot ]}$$
in which equations Lmot is an inductance of the motor (M) at 20° C. and 0 ampere, Φ is a flux of the motor (M) at 20° C. and 0 ampere, ωₘₒₜ is a speed of rotation of the motor (M), θₘₒₜ is an angular position of a rotor of the motor (M), k being a constant equal to 0 for phase 1, to 1 for phase 2 and to 2 for phase 3.

2. The method as claimed in claim 1, wherein the estimated currents (Iestx, Iesty) are determined by using a numerical analysis method for approximation of differential equations.

3. The method as claimed in claim 2, wherein the selected numerical analysis method for approximation of differential equations is the second-order Runge-Kutta method, with the following equations for calculating the estimated current (Iestx) for phase x, which is one of the two active phases:
$${[ \frac{dIestx}{dt} ]}_{n} = \frac{\begin{matrix}\begin{matrix}[ Umesx - ( \frac{Umesx + Umesy}{2} ) ] - \\ [ Rmot ] [ {Iestx}_{n} ] + \frac{\sqrt{3}}{2} * Φ *\end{matrix} \\ {ω}_{mot} * sin ( θ mot + \frac{π}{6} - k \frac{2 π}{3} )\end{matrix}}{[ Lmot ]} \\ [ {Iestx}_{n + \frac{1}{2}} ] = [ {Iestx}_{n} ] + {{\frac{Δ t}{2} [ \frac{dIestx}{dt} ]}_{n} \\ [ \frac{dIestx}{dt} ]}_{n + \frac{1}{2}} = \frac{\begin{matrix}\begin{matrix}[ Umesx - ( \frac{Umesx + Umesy}{2} ) ] - \\ [ Rmot ] [ {Iestx}_{n + \frac{1}{2}} ] + \frac{\sqrt{3}}{2} * Φ *\end{matrix} \\ {ω}_{mot} * sin ( θ mot + \frac{π}{6} - k \frac{2 π}{3} )\end{matrix}}{[ Lmot ]} \\ [ {Iestx}_{n + 1} ] = [ {Iestx}_{n} ] + Δ {t [ \frac{dIestx}{dt} ]}_{n + \frac{1}{2}}$$
in which Δt is the sampling time for the calculation and n is the number of iterations,
the equations for calculating the estimated current (Iesty) for phase y, which is the other one of the two active phases, being similar, with x being swapped for y and vice versa in the above equations.

4. The method as claimed in claim 1, wherein the correction of the two measured voltages (Ux, Uy) to produce a respective corrected voltage (Umesx, Umesy) is carried out initially by filtering of the measured voltages (Ux, Uy), which are then in the form of square waves, by means of a low-pass filter to produce a respective sinusoidal voltage, and then by compensation of the respective sinusoidal voltages by means of a compensator capable of compensating for the attenuating effects of the low-pass filter to produce a respective corrected voltage (Umesx, Umesy).

5. The method as claimed in claim 4, wherein the low-pass filter is a second- or higher-order low-pass filter.

6. The estimation method as claimed in claim 4, wherein the compensation uses an interpolation table on the basis of a speed of rotation (ωₘₒₜ) of the motor (M).

7. The method as claimed in claim 1, wherein the determination of the resistance (Rmot) of the motor is temperature-compensated by taking a mean temperature (Tmos) of the electronic elements of the switching device that are located near a temperature sensor, the resistance (Rmot) being compensated according to the following equation:
Rmot=Rmot20*(1+0.004*(Tmos−20° C.))
0.004 being the temperature coefficient of copper, and Rmot20 corresponding to the resistance of one phase of the motor (M) at 20° C.

8. A method for diagnosing a validity of measurements of a measured current (Imesx, Imesy) flowing through a respective phase of a winding of a permanent-magnet synchronous three-phase electric motor (M) of the type comprising at least one winding controllable by a switching device, the motor (M) then being controlled on two active phases, a third phase being in an open state, comprising:
the measured current (Imesx, Imesy) flowing through at least one of the two active phases is measured,
an estimated current (Iestx, Iesty) flowing through at least one of the two active phases of the winding is determined by means of the estimation method as claimed in claim 1,
a respective sliding standard deviation (Iecx or Iecy), for at least one of the two active phases, of a difference between the measured current (Imesx, Imesy) and the estimated current (Iestx, Iesty) for said at least one of the two active phases over a sliding horizon of a number of samples is calculated according to one of the following formulae, respectively:
$$Iecx = \sqrt{\frac{{\sum }_{i = 1}^{i = NbSample} {( Imesx - Iestx )}^{2}}{NbSample}}$$
$$Iecy = \sqrt{\frac{{\sum }_{i = 1}^{i = NbSample} {( Imesy - Iesty )}^{2}}{NbSample}}$$
NbSample being the number of samples,
the respective sliding standard deviation (Iecx, Iecy) for said at least one of the two active phases is compared with a predetermined threshold value, wherein, when the standard deviation is higher than the predetermined threshold value, an error in the measured currents (Imesx, Imesy) is diagnosed for said at least one phase and, when the standard deviation is lower than the predetermined threshold value, a validity of the measured currents (Imesx, Imesy) is diagnosed for said at least one of the two active phases.

9. The diagnosis method as claimed in claim 8, wherein it is implemented on the two active phases, with or without measurement of the current in the second active phase and, when the current is not measured in the second active phase, the value of the current in this second active phase is extrapolated from the measured current (Imesx or Imesy) of the first active phase, being equal to the negative value of the current of the first phase, the standard deviation being calculated according to the above formula given for this second phase.

10. The diagnosis method as claimed in claim 8, wherein the samples are taken in a range of angular positions of the motor (M) corresponding to a stabilized current in said at least one of the two phases.

11. The diagnosis method as claimed in claim 8, wherein it is applied to a physical or virtual current sensor capable of measuring a current in said at least one of the two active phases, the current sensor being characterized as faulty when the standard deviation is higher than the predetermined threshold value.
